(19) United States
(12) Patent Application Publication
(10) Pub. No.: US 2016/0093383 A1
(43) Pub. Date: Mar. 31, 2016

(54) METHOD AND APPARATUS FOR RELOCATING DATA IN NON-VOLATILE MEMORY

(71) Applicant: SanDisk Technologies Inc., Plano, TX (US)

(72) Inventor: Sourabh Sankule, Ujjain (IN)

(73) Assignee: SanDisk Technologies Inc., Plano, TX (US)

(21) Appl. No.: 14/700,716

(22) Filed: Apr. 30, 2015

(30) Foreign Application Priority Data
Sep. 30, 2014 (IN) 4933/CHE/2014

(51) Int. Cl. G11C 16/10

(52) U.S. Cl. CPC G11C 16/10

(57) ABSTRACT

Apparatus and methods implemented therein, in response to receiving an indication to program data to both a primary and secondary memory page determine whether a folding operation is in progress. In response to determining that the folding operation is in progress, programming of the data is delayed until completion of the folding operation. In response to determining the completion of the folding operation, data is programmed to the primary memory page and secondary memory page.

### REFERENCE TO RELATED APPLICATION

This application claims the benefit of Indian Application No. 4933/CHE/2014, filed on Sep. 30, 2014, which is hereby incorporated by reference herein in its entirety.

### TECHNICAL FIELD

This application relates generally to managing data in a memory system. More specifically, this application relates to relocating data from one memory block to another memory block in a solid state storage device.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Non-volatile memory systems, such as flash memory, are used in digital computing systems as a means to store data and have been widely adopted for use in consumer products. Flash memory may be found in different forms, for example in the form of a portable memory card that can be carried between host devices or as a solid state disk (SSD) embedded in a host device. These memory systems typically work with memory units called memory chunks, pages and memory blocks.

Non-volatile memory systems may perform various operations. For example, non-volatile memory systems may relocate data stored in one memory unit to another memory unit.

### SUMMARY

According to one aspect, a memory device comprising a wait determination module, a wait module and an initiate dual programming module is disclosed. The wait determination module is configured to, in response to an indication of a direct memory access (DMA) transfer, determine whether to wait before initiating dual programming of data into two sections of memory. The wait module is configured to, in response to the wait determination module determining to wait, wait until at least one memory operation is completed; and the initiate dual programming module is configured to, in response to wait module determining that the at least one memory operation is completed, initiate the dual programming of the data into the two sections of memory.

According to another aspect, a memory device determines whether to initiate a background operation in the memory device. The memory device assigns a higher priority to performing operations responsive to a host system command than to initiating the background operation. In response to determining to initiate the background operation, the background operation is initiated. After initiating the background operation, a host system command is received. Based on whether the background operation is completed, the memory device determines whether to delay initiation of one or more operations responsive to receipt of the host system command. In response to determining to delay initiation of the one or more operations responsive to receipt of the host system command, the memory device delays initiation of the one or more operations until completion of the background operation. Finally, in response to completion of the background operation, the memory device performs the one or more operations responsive to receipt of the host system command.

### BRIEF DESCRIPTION OF THE DRAWINGS

FIG. 1 illustrates a block diagram of host system and storage device according to one embodiment.

FIG. 2 is a block diagram of an example memory system/storage device that may implement methods described herein.

FIG. 3A illustrates an example physical memory organization of the memory in the storage device of FIG. 1.

FIG. 3B illustrates an expanded view of a portion of the physical memory of FIG. 2.

FIG. 4 is a timing diagram of one example of a folding operation in conjunction with a programming operation, in accordance with one embodiment.

FIG. 5 illustrates a timing diagram of another example of a folding operation in conjunction with a dual programming operation, in accordance with another embodiment.

FIG. 6 illustrates a timing diagram of a folding operation in conjunction with delaying a dual programming operation, in accordance with yet another embodiment.

### DETAILED DESCRIPTION

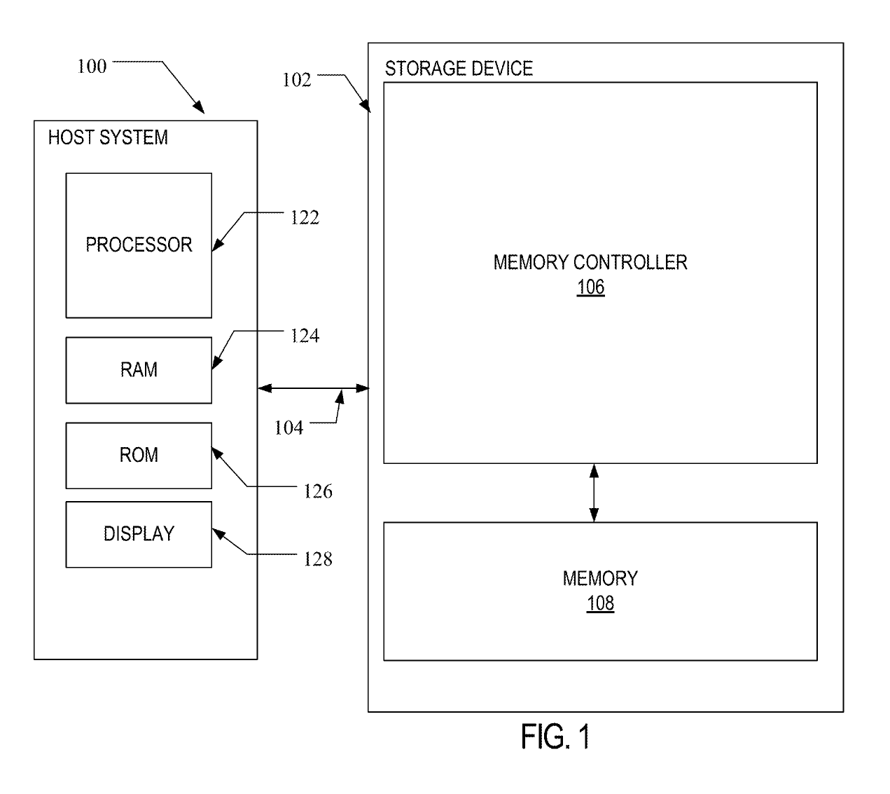

A system suitable for use in implementing aspects of the invention is shown in FIG. 1. A host system 100 stores data into, and retrieves data from, a storage device 102. The storage device 102 may be referred to as a memory system. The storage device 102 may be embedded in the host system 100 or may exist in the form of a card or other removable drive, such as a solid state disk (SSD) that is removably connected to the host system 100 through a mechanical and electrical connector conforming to an appropriate standard such as e-MMC, PCMCIA, CompactFlash or other known connector formats. The host system 100 may be any of a number of fixed or portable data generating devices, such as a personal computer, a mobile telephone, a personal digital assistant (PDA), or the like. The host system 100 communicates with the storage device 102 over an input/output interface 104.

In an embodiment, the storage device 102 comprises a memory controller 106 and a memory 108. Memory 108 may include semiconductor memory devices that store data. In an exemplary embodiment, methods implemented by the memory controller 106 may relocate data stored in the memory 108. The storage device 102 may be in the form of a portable flash drive, an integrated solid state drive or any of a number of known flash drive formats. In yet other embodiments, the storage device 102 may include only a single type of flash memory having one or more partitions.

Memory controller 106 operates to communicate data and program code back and forth between host system 100 and memory 108. The memory controller 106 may convert between logical addresses of data used by the host system 100 and physical addresses of memory 108 during programming and reading of data.

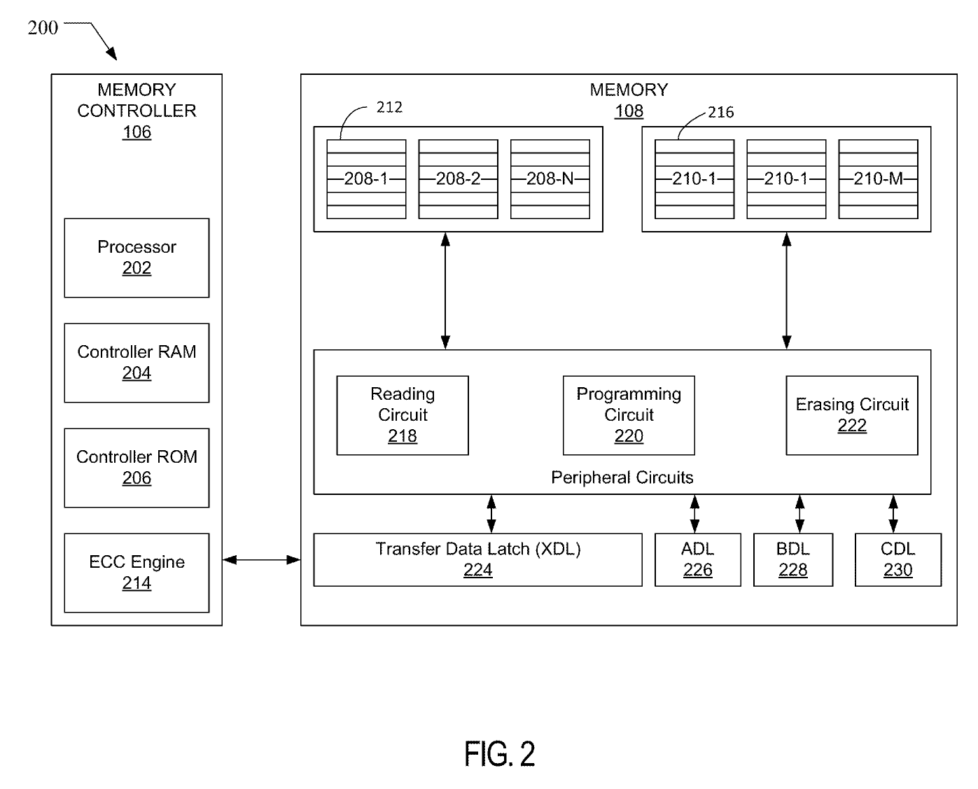

As discussed in more detail below, the storage device 102 may include functions for memory management. In operation, a processor, such as discussed below with respect to FIG. 2, may execute memory management instructions for operation of memory management functions. The memory management functions may control the assignment of the one or more portions of the memory 108 within storage device 102. In a preferred embodiment, memory management functions also include relocating stored data between different portions of memory 108.

FIG. 2 is a detailed block diagram of an example memory system 200. In this embodiment, the example memory system 200 corresponds to the storage device 102 of FIG. 1. The memory system 200 comprises a memory controller 106 and memory 108. The memory controller 106 includes a processor 202, controller RAM 204, controller ROM 206 and error correcting code (ECC) engine 214, in this embodiment. The processor 202 may comprise a microprocessor, a microcontroller, an application specific integrated circuit (ASIC), a field programmable gate array, a logical digital circuit, or other now known or later developed logical processing capability. Controller ROM 206 may store software instructions that processor 202 may execute to control the operation of memory system 200 and perform the data relocation methods described herein.

Memory 108 may correspond to any solid state non-volatile memory. Non-volatile memory retains information stored therein even if the storage device 102 is powered down or disconnected from host system 100. In an embodiment, memory 108 corresponds to NAND flash memory. In this embodiment, memory 108 is organized as memory pages. A memory page is the smallest writing unit of a NAND flash memory. Typically a memory page may store from 4 to 16 Kilobytes of data. A memory pages comprises single-level cells (SLC) or multi-level cells (MLC). An SLC stores a single bit of data per cell. An MLC memory stores multiple bits of data per cell. For example, a two-level MLC stores 2 bits of data per cell, a three-level MLC stores 3 bits of data per cell and N-level MLC stores N bits of data per cell.

Both types of cells (SLC and MLC) store data by storing electric charge (charge). The amount of charge stored in a cell is representative of the data bit(s) stored in the cell. For example, where no charge is stored in an SLC, the charge value represents a bit value of 0. In contrast, a predefined amount of charge stored in an SLC, represents the bit value of 1. In the case of an N-level MLC, different amounts of charge may be stored to represent anyone of the 2^{N} bits of data. For example, a two-level MLC is configured to store any one of four amounts of charge (2²=4).

In an embodiment, in response to receiving a request for a read, the reading circuit 218 of FIG. 2 translates the amount of charge stored in a memory cell to a binary representation of the data corresponding to the amount of charge stored in the cell. Programming circuit 220 translates data to a charge level and causes the corresponding charge to be stored in a memory cell.

Memory pages may be grouped together to form a physical memory block. In one embodiment, a memory block is smallest erasing unit. Data is written on a memory page by memory page basis. Erasing a memory page of a memory block requires erasure of all the memory pages of the memory block. Prior to erasing the memory block, all current data from the other memory pages of the memory block are moved to erased memory pages of another memory block. A memory block consisting of SLC type pages may be referred to as an SLC memory block. A memory block consisting of MLC type pages may be referred to as an MLC memory block. For example, sixteen 16 Kbytes SLC memory pages may be grouped to create a 256 Kilobytes memory block.

Referring back to FIG. 2, in an exemplary embodiment, memory 108 comprises N number of SLC memory blocks, 208-1 to 208-N and M number of 3-level MLC memory blocks, 210-1 to 201-M. Each row in a memory block represents a memory page. For example, memory page 212 is an SLC memory page that is a part of memory block 208-1 and memory page 216 is an MLC memory page that is a part of memory block 210-1. In this embodiment, a single 3-level MLC memory page may store three times the amount of data that may be stored in a single SLC memory page.

Memory 108 also includes a programming circuit 220, a reading circuit 218, a retouching circuit 222, transfer data latch (XDL) 224, data latch A (ADL) 226, data latch B (BDL) 228 and data latch C (CDL) 230. The XDL 224, ADL 226, BDL 228 and CDL 230 function as intermediate data storage between memory controller 106 and memory 108. When instructed by host system 100 to write data to memory 108, memory controller 106 transfers data to XDL 224. The programming circuit 220 then writes the data from XDL 224 to the specified memory block and page. By way of example and without limitation, the size of the XDL 224, ADL 226, BDL 228 and CDL 230 are each equal to the size of an SLC memory page. Similarly, when instructed to read data from a specified memory page, reading circuit 218 reads data from the specified memory page into the XDL 224. Memory controller 106 then transfers the read data from the XDL 224 to controller RAM 204.

Generally, writing data to an SLC memory block takes less time than writing the same amount data to an MLC memory block. However, an MLC memory block has a higher density than an SLC memory block. To take advantage of the speed of SLC and the higher density of MLC, memory 108 may comprise both SLC memory blocks and MLC memory blocks, as is the case of the memory 108 illustrated in FIG. 2. Where memory 108 comprises both SLC memory blocks and MLC memory blocks, it may be desirable first to store data into an SLC memory page of an SLC memory block, 212 for example, and subsequently move the data to a MLC memory page, 216 for example. Moving data from SLC memory blocks to MLC memory blocks may be performed by processor 202 either as a background operation or when memory system 200 is idle (e.g., not being accessed by host system 100). The process of moving valid data from SLC memory pages to one or more MLC memory pages may be referred to as folding. Examples of folding are discussed in U.S. Patent Application Publication No. 2001/0153911 A1, which is incorporated by reference herein in its entirety. After data is transferred from the SLC memory pages, the SLC memory pages may be erased and prepared to accept new data. Folding may also be performed on memory blocks. For example, data from three SLC memory blocks may be folded into a single 3-level MLC memory block. The memory pages of the SLC memory blocks may likewise be erased after the folding operation.

In an exemplary embodiment, after data is stored in three SLC memory pages, programming circuit 220 may move the data from the three SLC memory pages to a single 3 level MLC memory page. The movement may be effectuated by copying data from the first, second and third SLC memory pages to the ADL 226, BDL 228 and CDL 230, respectively. As discussed above, the 3 level MLC is merely for illustration purposes only. For example, when using N level MLC, N data latches may be used to copy data from N SLC memory pages.

In another exemplary embodiment, before transferring data received from host system 100 to XDL 224, ECC engine 214 may compute an ECC for the data. An example ECC is the low-density parity-check code (LDPC). The calculated ECC may be transferred to the XDL 224 along with the data. Programming circuit 220 may store the data and the ECC from the XDL 224 to an erased memory page. Separately, ECC engine 214 may compute the ECC for data in a memory page whenever the data read out from a memory page by memory controller 106. The memory controller 106 may read out the data from a memory page in response to receiving a request from host system 100. The ECC engine 214 may compare the computed ECC with the ECC that was stored in the memory page when the data was written to the memory page. Generally, if the number of bits in error or the bit error rate (BER) of the data of a memory page is below a threshold, the ECC engine 214 may utilize the ECC stored with the data to recover the bits in error.

In another embodiment, in response to data and computed ECC being transferred to XDL 224, programming circuit 222 may write the data and the computed ECC into an erased primary SLC memory page and an erased secondary SLC memory page. Storing a copy of the data and the ECC into each of a primary and a secondary memory page may be referred to as dual programming.

After data is stored into the primary SLC memory page and the secondary SLC memory page, processor 202 may read the data and corresponding ECC from the primary SLC memory page and, using the ECC engine 214, may verify if there are errors in the read data. If no errors are detected by ECC engine 214, processor 202 may commit the data written to the primary memory page. Separately, if all the errors in the data stored in the primary memory page can be corrected by the ECC engine 214 (i.e., no uncorrectable errors), the data in the primary memory page may be committed. The secondary SLC memory page may be reclaimed and erased. This process of committing data after verification and validation may be referred to as enhanced post write read (EPWR).

However, if the errors in the data stored in the primary SLC memory page are uncorrectable because the number of bits in error exceeds the computational capabilities of the ECC engine 214, the data stored in the secondary SLC memory page may be utilized to correct the uncorrectable errors. In this case, the primary memory page may be reclaimed and erased and the corrected data stored in the secondary memory page may be committed.

For example, in response to determining that the data stored in the primary SLC memory page are uncorrectable, the processor 202 may read the data and corresponding ECC from the secondary SLC memory page and, using the ECC engine 214, may verify if there are errors in the read data. Similar to reading from the primary SLC memory page, if no errors are detected by ECC engine 214, processor 202 may commit the data written to the secondary memory page. Separately, if all the errors in the data stored in the secondary memory page can be corrected by the ECC engine 214, the data in the secondary memory page may be committed. However, if the errors in the data stored in the secondary SLC memory page are uncorrectable because the number of bits in error exceeds the computational capabilities of the ECC engine 214, the processor 202 may attempt to rewrite the data from the latches to one or more SLC memory pages, as discussed in more detail below.

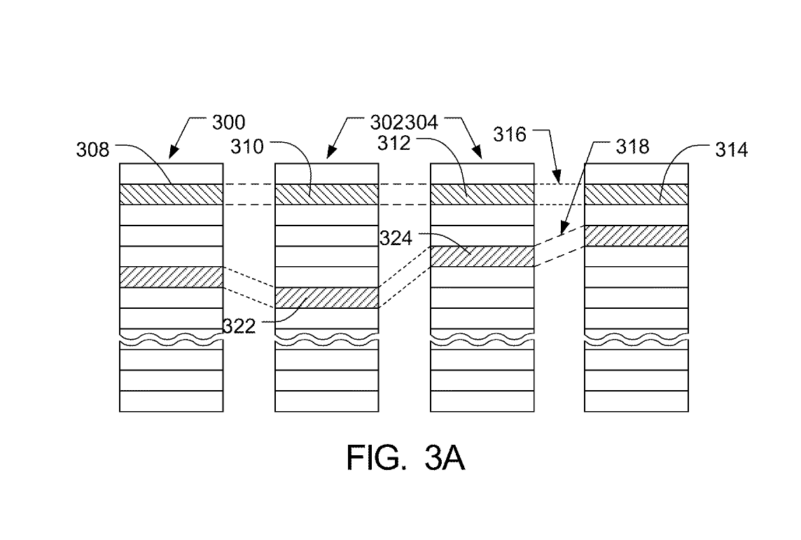

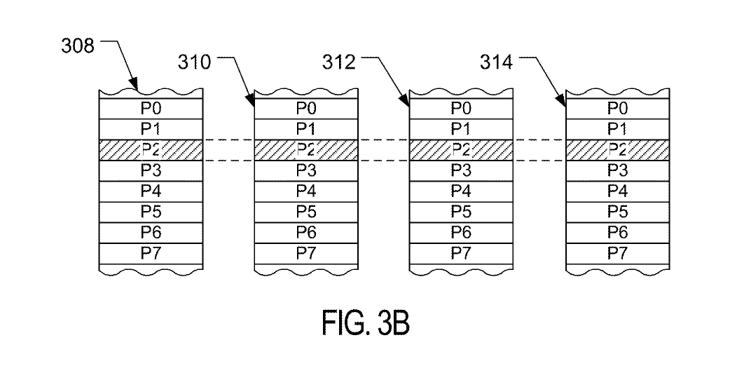

Referring to FIG. 3A, memory 108 (e.g., SLC and MLC flash respectively) may be arranged in blocks of memory cells. In the example of FIG. 3A, four planes or sub-arrays 300, 302, 304 and 306 memory cells are shown that may be on a single integrated memory cell chip, on two chips (two of the planes on each chip) or on four separate chips. The specific arrangement is not important to the discussion below and other numbers of planes may exist in a system. The planes are individually divided into blocks of pages shown in FIG. 3A by rectangles, such as pages 308, 310, 312 and 314, located in respective planes 300, 302, 304 and 306. There may be dozens or hundreds of blocks in each plane. Pages may be logically linked together to form a memory block that may be erased as a single unit. For example, pages 308, 310, 312 and 314 may form a first memory block 316. The pages used to form a memory block need not be restricted to the same relative locations within their respective planes, as is shown in the second memory block 318 made up of memory pages 320, 322, 224 and 226.

A memory block 302 is illustrated in FIG. 3B as formed of one physical page for each of the four pages 308, 310, 312 and 314. The blocks disclosed in FIGS. 3A-3B are referred to herein as physical blocks because they relate to groups of physical memory cells as discussed above. As previously discussed and as used herein, a logical block is a virtual unit of address space defined to have the same size as a memory page. Each logical block includes a range of logical block addresses (LBAs) that are associated with data received from a host system 100. The LBAs are then mapped to one or more memory chunks in the storage device 102 where the data is physically stored.

As discussed below, there are several methods to fold data from SLC memory pages to an MLC memory page. The methods discussed may be implemented, for example, in the storage device 102 (FIG. 1). As previously mentioned, the folding operation may be performed as a background operation by the programming circuit 220, for example.

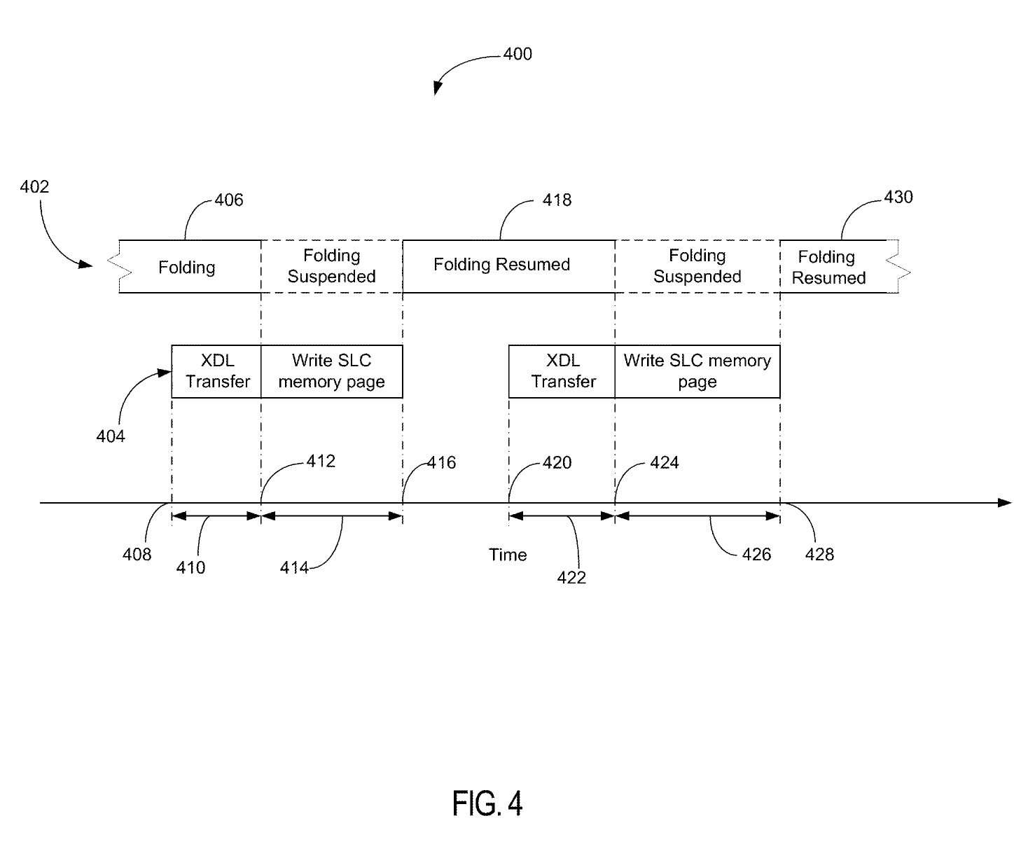

FIG. 4 is a timing diagram 400 that illustrates the folding operation 402 being performed by programming circuit 220 in the background at least partly while data transfer to XDL 224 and programming of the transferred data, collectively 404, occurs in the foreground. 406 represents folding of data from three previously written SLC memory pages to a single 3-level MLC memory page.

At time 408, host system 100 may request memory controller 106 to store data to memory 108. At approximately time 408, memory controller 106 may transfer the data along with an ECC computed by ECC engine 214 to XDL 224. The transfer may take place using a direct memory access (DMA) operation for a time duration corresponding to 410. In this regard, the transfer to XDL 224 may be performed separately from the folding operation 402. At time 412, programming circuit 220 may suspend the folding operation 406 and write the data from the XDL 224 to an erased SLC memory page. Time 414 represents the time duration for the write operation. At time 416, the write operation completes and the suspended folding operation 418 is resumed.

At time 420, host system 100 may request memory controller 106 to store data to memory 108. At approximately time 420, memory controller 106 may transfer the data along with an ECC computed by ECC engine 214 to XDL 224. The transfer may take place using a direct memory access (DMA) operation for a time duration corresponding to 422. At time 424, programming circuit 220 may suspend the folding operation 418 and write the data from the XDL 224 to an erased SLC memory page. Time 426 represents the time duration for the write operation. At time 428, the write operation completes and the suspended folding operation 430 is resumed.

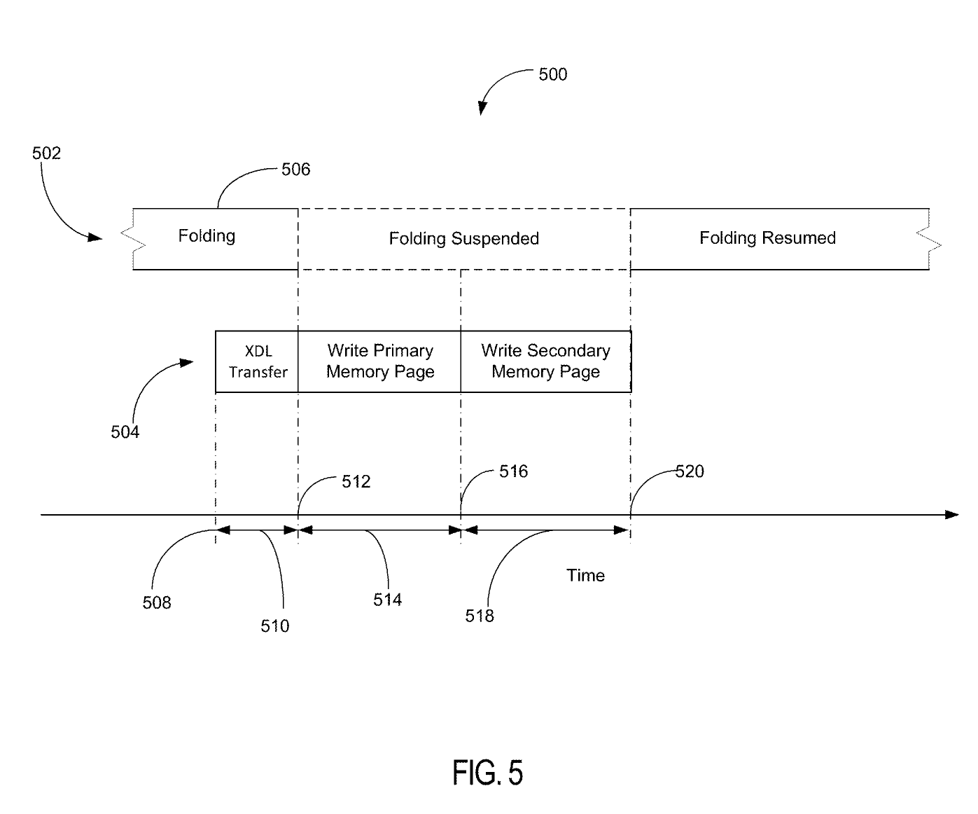

FIG. 5 is a timing diagram 500 of a folding operation 502 being performed in the background with dual programming 504 being performed in the foreground. 506 represents folding of data from three previously written SLC memory pages to a single 3-level MLC memory page.

At time 508, host system 100 may request memory controller 106 to store data to memory 108. At approximately time 508, memory controller 106 may transfer the data along with an ECC computed by ECC engine 214 to XDL 224. The transfer may take place using a direct memory access (DMA) operation for a time duration corresponding to 510. At time 512, programming circuit 220 may suspend the folding operation 506 and write the data from the XDL 224 to an erased primary SLC memory page. Time 514 represents the time duration for the write operation to the primary SLC memory page. At time 516, the write operation to the primary SLC memory page completes. At approximately time 516, programming circuit 220 initiates programming of the data to an erased secondary SLC memory page. After time duration 518, programming of the data to the secondary SLC memory page completes at time 520 and the suspending folding operation 506 is resumed.

In an exemplary embodiment, based on the implementation of the programming circuit 220, after completion of the programming of the primary SLC memory page, the contents of the XDL 224 may be erased. This occurs in part because of the suspended folding operation 506. Because the contents of the XDL 224 are erased, the data that is stored into the secondary memory page will be incorrect.

In an exemplary embodiment, before initiating the storage of data to the primary and secondary SLC memory pages, programming circuit 220 may check if another operation, such as a folding operation, is in progress. In response to determining that the other operation is a program operation (e.g., if a folding operation is in progress), programming circuit 220 may wait for the other operation to complete (e.g., the folding operation to complete) before initiating storage of data to the primary and secondary memory pages.

So that, the memory device, when deciding whether to initiate the background operation, may view the background operation as a lower priority than host system operations; however, once the background operation is initiated, the priority of the background operation vis-à-vis the host system operations may change (e.g., the completion of the background operation may be given a higher priority).

In this regard, after the background operation is initiated, the completion of the background operation, such as folding, may take precedence over a foreground operation. As discussed above, background operations may be performed during idle time. The background operations may comprise internal storage device operations, such as folding. More specifically, the folding operation may be initiated when the storage device is not performing any operations in response to a host system command, such as a host system read command or a host system write command. In this way, initiation of the background operation is of a lower precedence than performing a host system command. In one embodiment, after the background operation is initiated, the completion of the background operation may take precedence over initiating and/or performing operations responsive to receipt of the host system command. For example, when the storage device 102 receives a host system command, the storage device may wait to perform actions responsive to receipt of the host system command for a specific amount of time (such as waiting until the folding operation completes). In effect, in one stage of the background operation (initiating the background operation), the background operation takes a lower precedence with respect to initiating and/or performing operations responsive to a host system command. Further, in another stage of the background operation (performing the background operation), the background operation takes a higher precedence with respect to initiating and/or performing operations responsive to a host system command. More specifically, the storage device attributes performing and/or completing the background operation to a higher precedence than performing operations responsive to receipt of the host system command. The discussion below relates to a background folding operation for illustration purposes. Other background operations are contemplated.

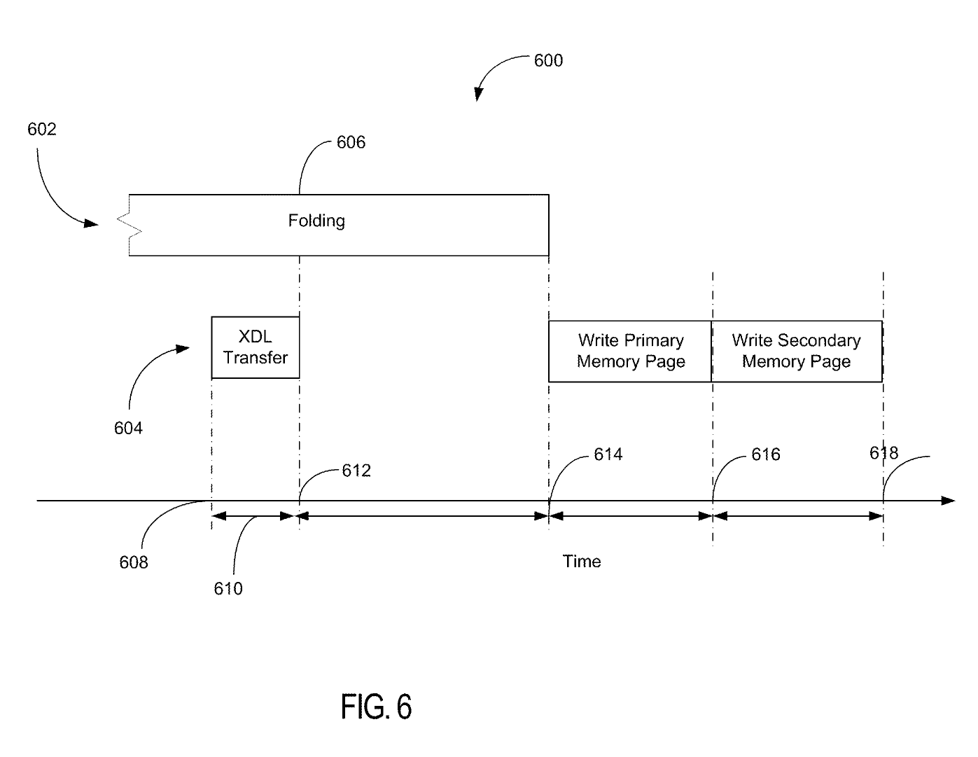

FIG. 6 is a timing diagram 600 that illustrates operation of this embodiment. Folding operation 602 is being performed in the background with dual programming 604 being performed in the foreground. 606 represents folding of data from three previously written SLC memory pages to a single 3-level MLC memory page.

At time 608, host system 100 may request memory controller 106 to store data to memory 108. At approximately time 608, memory controller 106 may transfer the data along with an ECC computed by ECC engine 214 to XDL 224. The transfer may take place using a direct memory access (DMA) operation for a time duration corresponding to 610. As discussed above, the DMA operation may be performed independently of the folding operation 602. At time 612, after completion of the data transfer to XDL 224, programming circuit may determine if a folding operation is in progress. In response to determining that a folding operation 606 is in progress, programming circuit 220 may delay the writing of data from XDL 224 to a primary SLC memory page. As discussed above, the background operation (e.g., folding) takes precedence over the foreground operation (e.g., writing of data from XDL 224 to the primary SLC memory page). At time 614, programming circuit 220 may determine that folding operation 606 is complete. Programming circuit 220 may prevent initiation of additional folding operations until after the foreground operations complete (e.g., until after the writing of data from XDL 224 to the primary SLC memory page and to the secondary SLC memory page). In response to determining that the folding operation 102 is completed, programming circuit 220 may initiate storage of data from XDL 224 to an erased primary SLC memory page. After completion of the storage operation, at time 616, programming circuit 220 may initiate storage of data from XDL 224 to an erased secondary SLC memory page. At time 618, after completion of the storage of data to the erased secondary SLC memory page, programming circuit 220 may allow a new folding operation to be initiated. Delaying of the write operation to allow a background operation to complete may also be implemented in an embodiment, where only a single copy of the data is stored in a memory page, as in the scenario illustrated in FIG. 4.

Semiconductor memory devices include volatile memory devices, such as dynamic random access memory (“DRAM”) or static random access memory (“SRAM”) devices, non-volatile memory devices, such as resistive random access memory (“ReRAM”), electrically erasable programmable read only memory (“EEPROM”), flash memory (which can also be considered a subset of EEPROM), ferroelectric random access memory (“FRAM”), and magnetoresistive random access memory (“MRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse, phase change material, etc., and optionally a steering element, such as a diode, etc. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array. NAND and NOR memory configurations are exemplary, and memory elements may be otherwise configured.

The semiconductor memory elements located within and/or over a substrate may be arranged in two or three dimensions, such as a two dimensional memory structure or a three dimensional memory structure.

In a two dimensional memory structure, the semiconductor memory elements are arranged in a single plane or a single memory device level. Typically, in a two dimensional memory structure, memory elements are arranged in a plane (e.g., in an x-z direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three dimensional memory array is arranged so that memory elements occupy multiple planes or multiple memory device levels, thereby forming a structure in three dimensions (i.e., in the x, y and z directions, where the y direction is substantially perpendicular and the x and z directions are substantially parallel to the major surface of the substrate).

As a non-limiting example, a three dimensional memory structure may be vertically arranged as a stack of multiple two dimensional memory device levels. As another non-limiting example, a three dimensional memory array may be arranged as multiple vertical columns (e.g., columns extending substantially perpendicular to the major surface of the substrate, i.e., in the y direction) with each column having multiple memory elements in each column. The columns may be arranged in a two dimensional configuration, e.g., in an x-z plane, resulting in a three dimensional arrangement of memory elements with elements on multiple vertically stacked memory planes. Other configurations of memory elements in three dimensions can also constitute a three dimensional memory array.

By way of non-limiting example, in a three dimensional NAND memory array, the memory elements may be coupled together to form a NAND string within a single horizontal (e.g., x-z) memory device levels. Alternatively, the memory elements may be coupled together to form a vertical NAND string that traverses across multiple horizontal memory device levels. Other three dimensional configurations can be envisioned wherein some NAND strings contain memory elements in a single memory level while other strings contain memory elements which span through multiple memory levels. Three dimensional memory arrays may also be designed in a NOR configuration and in a ReRAM configuration.

Typically, in a monolithic three dimensional memory array, one or more memory device levels are formed above a single substrate. Optionally, the monolithic three dimensional memory array may also have one or more memory layers at least partially within the single substrate. As a non-limiting example, the substrate may include a semiconductor such as silicon. In a monolithic three dimensional array, the layers constituting each memory device level of the array are typically formed on the layers of the underlying memory device levels of the array. However, layers of adjacent memory device levels of a monolithic three dimensional memory array may be shared or have intervening layers between memory device levels.

Then again, two dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three dimensional memory arrays. Further, multiple two dimensional memory arrays or three dimensional memory arrays (monolithic or non-monolithic) may be formed on separate chips and then packaged together to form a stacked-chip memory device.

Associated circuitry is typically required for operation of the memory elements and for communication with the memory elements. As non-limiting examples, memory devices may have circuitry used for controlling and driving memory elements to accomplish functions such as programming and reading. This associated circuitry may be on the same substrate as the memory elements and/or on a separate substrate. For example, a controller for memory read-write operations may be located on a separate controller chip and/or on the same substrate as the memory elements.

One of skill in the art will recognize that this invention is not limited to the two dimensional and three dimensional exemplary structures described but cover all relevant memory structures within the spirit and scope of the invention as described herein and as understood by one of skill in the art.

Further embodiments can be envisioned by one of ordinary skill in the art after reading the foregoing. In other embodiments, combinations or sub-combinations of the above disclosed invention can be advantageously made. The block diagrams of the architecture and flow diagrams are grouped for ease of understanding. However it should be understood that combinations of blocks, additions of new blocks, re-arrangement of blocks, and the like are contemplated in alternative embodiments of the present invention.

The specification and drawings are, accordingly, to be regarded in an illustrative rather than a restrictive sense. It will, however, be evident that various modifications and changes may be made thereunto without departing from the broader spirit and scope of the invention as set forth in the claims.

1. A memory device comprising:
a wait determination module configured to, in response to an indication of a direct memory access (DMA) transfer, determine whether to wait before initiating dual programming of data into two sections of memory;
a wait module configured to, in response to the wait determination module determining to wait, wait until at least one memory operation is completed; and
an initiate dual programming module configured to, in response to the wait module determining that the at least one memory operation is completed, initiate the dual programming of the data into the two sections of memory.

2. The memory device of claim 1, wherein the two sections of memory comprise two single-level cell pages.

3. The memory device of claim 1, wherein the at least one memory operation comprises a background operation, the background operation being triggered by the memory device and separate from host system operations.

4. The memory device of claim 3, further comprising an initiate background operation determination module configured to determine whether to initiate the background operation.

5. The memory device of claim 4, wherein the initiate background operation determination module is configured to assign a higher priority to performing operations responsive to a host system command than to initiating the background operation.

6. The memory device of claim 5, wherein, prior to initiation of the background operation, the initiate background determination module assigns the higher priority to performing operations responsive to a host system command than to initiating the background operation; and
wherein, after initiation of the background operation, the wait determination module assigns a higher priority to completing the background operation than to initiating dual programming of the data into the two sections of memory.

7. The memory device of claim 5, wherein the background operation comprises a folding operation.

8. The memory device of claim 7, wherein the wait determination module is configured to determine whether to wait before initiating dual programming of data into the two sections of memory by determining whether the memory device is currently performing the folding operation.

9. The memory device of claim 8, wherein, in response to determining that the memory device is currently performing the folding operation, the wait determination module is configured to wait until the folding operation is completed before initiating dual programming of data in to the two sections of memory.

10. The memory device of claim 1, wherein the memory comprises a silicon substrate and a plurality of memory cells forming a monolithic three-dimensional structure, wherein at least one portion of the memory cells is vertically disposed with respect to the silicon substrate.

11. A method comprising:
performing by a memory device:
determining whether to initiate a background operation in the memory device, wherein the memory device assigns a higher priority to performing operations responsive to a host system command than to initiating the background operation;
in response to determining to initiate the background operation, initiating the background operation;
after initiating the background operation, determining to perform one or more operations in response to receipt of a host system command;
determining, based on whether the background operation is completed, whether to delay initiation of the one or more operations responsive to receipt of the host system command;
in response to determining to delay initiation of the one or more operations responsive to receipt of the host system command, delaying until completion of the background operation; and
in response to completion of the background operation, performing the one or more operations responsive to receipt of the host system command.

12. The method of claim 11, wherein the background operation comprises a folding operation.

13. The method of claim 12, wherein the host system command comprises a write command.

14. The method of claim 13, wherein the one or more operations responsive to receipt of the host system command comprise dual programming operations in order to program data the two sections of memory.

15. The method of claim 11, wherein determining whether to initiate a background operation comprises:
determining whether the memory device is performing operations responsive to any host system command; and
in response to determining that the memory device is not performing any operations responsive to any host system command, determining to initiate the background operation.

16. The method of claim 15, wherein, prior to initiating the background operation, the memory device assigns a higher priority to performing operations responsive to the host system command than to initiating the background operation; and
wherein, after initiating the background operation, the memory device assigns a higher priority to completing the background operation than to performing operations responsive to the host system command.

17. The method of claim 16, wherein the background operation comprises a folding operation.

18. A method comprising:
performing by a memory device:
determining whether a folding operation is in progress, in response to receiving an indication to program data to both a primary and secondary memory page;
in response to determining that the folding operation is in progress, delaying a programming of the data; and
initiating programming of the data to the primary memory page and secondary memory page depending on performance of the folding operation.

19. The method of claim 18, wherein initiating programming of the data to the primary memory page and secondary memory page is dependent on completion of the folding operation.

20. The method of claim 19, wherein, prior to initiating the folding operation, the memory device assigns a higher priority to performing operations responsive to the host system command than to folding operations.

21. The method of claim 20, wherein, after initiating the folding operation, the memory device assigns a higher priority to completing the folding operation than to performing at least some operations responsive to the host system command.
